(19) United States
(12) Patent Application Publication
(10) Pub. No.: US 2026/0035233 A1
(43) Pub. Date: Feb. 5, 2026

(54) DIAPHRAGM AND MEMS MICROPHONE

(71) Applicant: AAC Technologies Pte. Ltd., Singapore (SG)

(72) Inventors: Minh Ngoc Nguyen, Bac Ninh (VN); Yannick Pierre Kervran, HK (FR)

(21) Appl. No.: 18/789,636

(22) Filed: Jul. 30, 2024

(51) Int. Cl. B81B 3/00; H04R 7/14

(52) U.S. Cl. CPC B81B 3/0072; H04R 7/14; B81B 2201/0257; B81B 2203/0127; H04R 2201/003; H04R 2307/023

(57) ABSTRACT

Embodiments of the present disclosure disclose a diaphragm and a MEMS microphone. The diaphragm includes a vibrating portion and a connecting portion provided around the vibrating portion. The vibrating portion includes a first flat portion disposed in a central position of the vibrating portion, a corrugated portion disposed around the first flat portion, and a second flat portion disposed around the corrugated portion. The corrugated portion extends in a direction from a center to an edge of the first flat portion, the corrugated portion has a flexural rigidity larger than a flexural rigidity of the first flat portion and a flexural rigidity of the second flat portion, and the corrugated portion is made of a material including at least silicon nitride. The diaphragm and the MEMS microphone provided in the embodiment of the present disclosure can improve the structural strength of the diaphragm.

### TECHNICAL FIELD

The various embodiments described in this document relate in general to the technical field of microphones, and more specifically to a diaphragm and a MEMS microphone.

### BACKGROUND

With the continuous development of electronic technology, all kinds of electronic devices are becoming more and more miniaturized and thinner as a whole while becoming more and more functional, which means that the layout space left for various components in the electronic devices is getting smaller and smaller. The microphone, as an important component in the electronic device, also need to be designed small to achieve occupying of less space for the limited layout space in the electronic device. The micro-electro-mechanical system (MEMS) microphone is a kind of microphone with small volume, which is made by micro-machining technology, and has good frequency response characteristics and low noise. At present, the MEMS microphones are widely used in different electronic devices.

The MEMS microphone includes a substrate, a diaphragm, and a back plate. The diaphragm is an important part of the MEMS microphone, and a structural strength of the diaphragm affects the normal operating of the MEMS microphone. Therefore, how to improve the structural strength of the diaphragm is a technical problem to be solved.

### SUMMARY

The embodiment of the present disclosure aims to provide a diaphragm and a MEMS microphone, which can improve the structural strength of the diaphragm.

In order to solve the above technical problems, embodiments of the present disclosure provide a diaphragm. The diaphragm includes a vibrating portion and a connecting portion provided around the vibrating portion. The vibrating portion includes a first flat portion disposed in a central position of the vibrating portion, a corrugated portion disposed around the first flat portion, and a second flat portion disposed around the corrugated portion. The corrugated portion extends in a direction from a center to an edge of the first flat portion, the corrugated portion has a flexural rigidity larger than a flexural rigidity of the first flat portion and a flexural rigidity of the second flat portion, and the corrugated portion is made of a material including at least silicon nitride.

Embodiments of the present disclosure further provide a MEMS microphone including a substrate having a back cavity and a capacitive structure disposed on the substrate. The capacitance structure includes a diaphragm and a back plate disposed spaced apart from the diaphragm, where the diaphragm is the diaphragm described above.

According to the diaphragm and the MEMS microphone provided in the embodiments of the present disclosure, the corrugated structure is made of a material including at least silicon nitride, so that the flexural rigidity of the corrugated portion is larger than that of other portions. By using a material, at the corrugated structure, with higher flexural rigidity than other portions, the corrugated portion has higher structural strength than other portions, thereby reducing the risk of cracking and failure of the diaphragm.

In some embodiments, each of the first flat portion and the second flat portion includes a polysilicon material, and the corrugated portion includes a silicon nitride material. In this way, the corrugated portion can be fabricated by using the silicon nitride having a better flexural rigidity than polysilicon, such that the structural strength of the corrugated portion can be effectively improved.

In some embodiments, the corrugated portion includes a base layer having an end connected with the first flat portion and another end connected with the second flat portion, and at least one reinforcing layer disposed on the base layer, where the at least one reinforcing layer includes a silicon nitride material. In this way, the reinforcing layer with higher flexural rigidity is attached to the corrugated structure, so that the corrugated portion has a higher structural strength than other portions.

In some embodiments, the base layer includes a polysilicon or silicon nitride material. Thus, the manufacturing material of the base layer of the corrugated portion can be selected according to actual needs.

In some embodiments, the at least one reinforcing layer is entirely disposed on the base layer in the direction from the center to the edge of the first flat portion. In this way, by completely covering the base layer with the reinforcing layer, such that the structural strength at any position of the base layer can be improved.

In some embodiments, the base layer includes concave portions and convex portions that are alternatingly disposed in the direction from the center to the edge of the first flat portion. The at least one reinforcing layer is embodied as a plurality of reinforcing layers in the direction from the center to the edge of the first flat portion, each respective reinforcing layer of the plurality of reinforcing layers is disposed on a respective entire concave portion and a portion of each of a pair of convex portions adjacent to the respective concave portion. Adjacent reinforcing layers located on a same convex portion of the convex portions are spaced apart from each other by a spacing. In this way, the reinforcing layer can be provided at a weak position of the base layer, and the structural strength at the weak position of the base layer can be improved.

In some embodiments, the first flat portion and the second flat portion each have a protrusion portion extending from a side of an end of the first flat portion or the second flat portion close to the corrugated portion, and the protrusion portion is disposed on an edge of the corrugated portion. In this way, the connection reliability between the flat portions and the corrugated portion can be enhanced through the protrusion portion.

In some embodiments, the thickness of the corrugated portion is less than the thickness of the flat portion. Therefore, the mechanical sensitivity of the corrugated portion can be ensured by reducing the thickness of the corrugated portion while the corrugated portion has sufficient flexural rigidity.

In some embodiments, the reinforcing layer of the diaphragm is provided on at least one of a side of the corrugated portion close to the back plate and a side of the corrugated portion facing away from the back plate. In this way, the flexural rigidity of the corrugated portion can be improved by providing the reinforcing layer on one side of the corrugated portion or simultaneously providing reinforcing layers on both sides of the corrugated portion.

### BRIEF DESCRIPTION OF THE DRAWINGS

One or more embodiments are exemplary illustrated by the pictures in the accompanying drawings, which do not constitute a limitation to the embodiments, elements having the same reference numeral signs in the accompanying drawings are represented as similar elements, and the drawings in the drawings do not constitute a scale limitation unless otherwise stated.

FIG. 1 is a schematic diagram of a partial structure of a diaphragm provided in some embodiments of the present disclosure.

FIG. 2 is a cross-sectional view of the partial structure of the diaphragm of FIG. 1 along line A-A.

FIG. 3 is a schematic diagram of a partial structure of a diaphragm provided in other embodiments of the present disclosure.

FIG. 4 is a cross-sectional view of the partial structure of the diaphragm of FIG. 3 along line B-B.

FIG. 5 is a cross-sectional schematic view of a diaphragm provided in further embodiments of the present disclosure.

FIG. 6 is a schematic structural diagram of a MEMS microphone provided in some embodiments of the present disclosure.

FIG. 7 is a schematic diagram of a partial structure of a diaphragm and a back plate cooperating with the diaphragm in a MEMS microphone provided in some embodiments of the present disclosure.

### DETAILED DESCRIPTION OF THE EMBODIMENTS

In order to make the purpose, technical solutions, and advantages of the embodiments of the present disclosure clearer, the embodiments of the present disclosure will be described in detail in conjunction with the accompanying drawings below. However, it will be appreciated by those of ordinary skill in the art that in embodiments of the present disclosure, many technical details have been proposed to enable the reader to better understand the present disclosure. However, even without these technical details and variations and modifications based on the following embodiments, the technical solution required to be protected by this application can be achieved. The following embodiments are divided for convenience of description and should not constitute any limitation on the specific implementation of the present disclosure. The embodiments may be combined and referenced to each other without contradiction.

Unless otherwise defined, all technical and scientific terms used herein have the same meanings as the meaning commonly understood by those skilled in the art. The terms used herein are for the purpose of describing specific embodiments only and are not intended to limit the present disclosure. The terms “including/comprising” and “has/have” and any variations thereof in the description and claims of this application and the above drawings are intended to cover non-exclusive inclusion.

In the description of embodiments of the present disclosure, unless otherwise expressly stipulated and limited, the technical terms “installation”, “coupling” and “connection” are to be understood in a broad sense, for example, they may mean fixed connections, detachable connections, or integrated formed. They may also mean a mechanical connection or an electrical connection. They may also mean a directly connection or indirectly connection through an intermediate medium, or they may mean a connection within two elements or an interaction relationship between two elements. For those of ordinary skill in the art, the specific meanings of the above-mentioned terms in embodiments of the present disclosure can be understood according to the specific situations.

The MEMS microphone includes a diaphragm and a back plate, which are processed on a silicon substrate through a micro-machining technology. The back plate has at least one through hole. The diaphragm and the back plate are spaced apart from each other by an air spacing, such that the diaphragm and the back plate form a variable capacitor with the air spacing. When the diaphragm vibrates in response to impact of external sound waves or sound pressure, the capacitor can convert sound energy into electrical energy for detection.

Due to the MEMS microphone having a small size, the MEMS microphone is easily integrated in various electronic devices. However, the microphone may sacrifice sensitivity while reducing size. In practice, the sensitivity of the MEMS microphone can be improved by low-stress control of the diaphragm in the MEMS microphone. Moreover, power consumption can be greatly reduced.

Generally, there may be residual stress in the diaphragm during manufacturing or operating of the diaphragm. The residual stress of the diaphragm is an important factor leading to the reduction of sensitivity. Excessive residual stress may lead to a decline in the flexibility of the diaphragm and affect the vibration characteristics of the diaphragm. In order to reduce the residual stress of the diaphragm and improve the compliance of the diaphragm, a corrugated diaphragm appears, that is, the diaphragm is provided with a corrugated structure. The corrugated structure can improve the mechanical sensitivity of the diaphragm. The number of corrugations and a depth of each of the corrugations can be set according to the actual situation. During actually processing of the diaphragm, with the increase of the depth of the corrugation, the diaphragm may be easily damaged during the process.

When the corrugated structure is provided on the diaphragm, high stress concentration creates from the edge of corrugations, so the strength of the corrugated structure is insufficient, which may easily make breakage and failure of the diaphragm. In order to improve the strength of the diaphragm, embodiments of the present disclosure provide a diaphragm. The corrugated structure of the diaphragm is made by a material with a higher flexural rigidity than a flexural rigidity of the diaphragm body, or the corrugated structure of the diaphragm is superimposed with a reinforcing layer with a higher flexural rigidity than the flexural rigidity of the diaphragm body. In this way, the strength of the corrugated structure of the diaphragm can be improved, and the ability to resist deformation at the corrugated structure can be improved, thereby avoiding the phenomenon of bending and breaking easily at the corrugated structure of the diaphragm and improving the structural strength of the diaphragm.

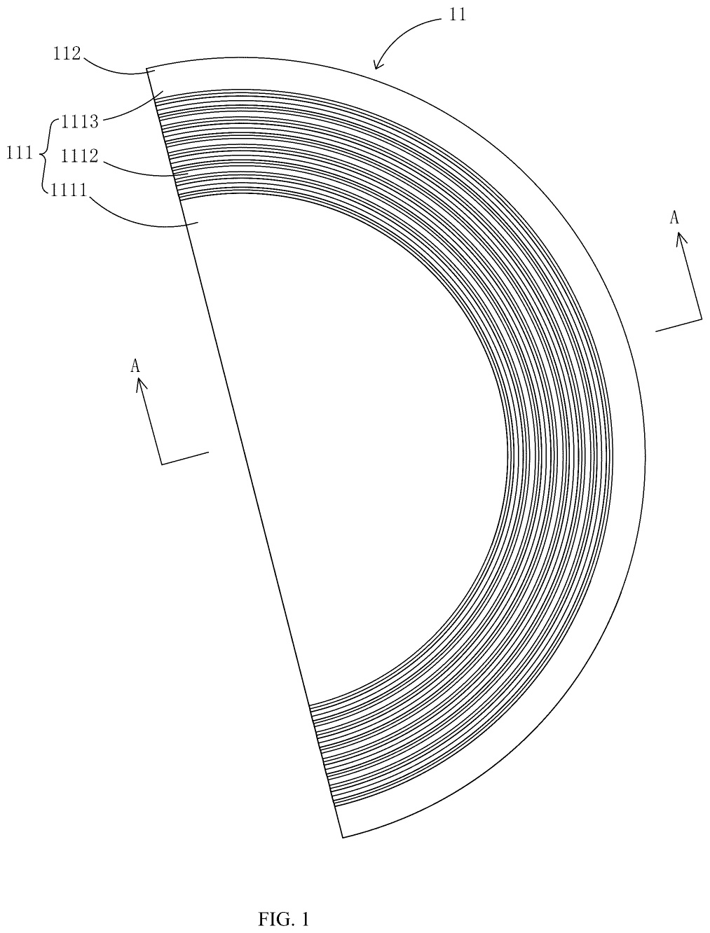

The diaphragm provided in some embodiments of the present disclosure will be described below with reference to FIGS. 1 to 5.

As shown in FIGS. 1 to 5, the diaphragm 11 provided in some embodiments of the present disclosure includes a vibrating portion 111 and a connecting portion 112 provided around the vibrating portion 111. The vibrating portion 111 includes a first flat portion 1111 disposed in a central position of the vibrating portion 111, a corrugated portion 1112 disposed around the first flat portion 1111, and a second flat portion 1113 disposed around the corrugated portion 1112. The corrugated portion 1112 extends in a direction from a center to an edge of the first flat portion 1111. The corrugated portion 1112 has a flexural rigidity larger than that of the first flat portion 1111 and that of the second flat portion 1113. The corrugated portion 1112 is made of a material including at least silicon nitride.

The vibrating portion 111 is a portion in which the diaphragm 11 vibrates in response to the sound waves. The connecting portion 112 is a portion in which the diaphragm 11 is connected to the substrate and fixed to the substrate. The vibrating portion 111 of the diaphragm 11 faces the back plate, a side of the vibrating portion 111 faces the back plate, and the other side of the vibrating portion 111 faces the back cavity of a substrate. Generally, the back plate does not deform, so a magnitude of the vibration displacement of the diaphragm 11 affects the capacitance value, thereby affecting the sensitivity of the microphone. In the disclosure, the corrugated structure formed by the corrugated portion 1112 improves the sensitivity of the diaphragm 11.

The corrugated portion 1112 is disposed around the first flat portion 1111, and the first flat portion 1111 is disposed in the central position of the vibrating portion 111, which can respond in time under the action of sound pressure. The corrugated portion 1112 may be located near the edge of the vibrating portion 111. In addition, a relatively flat portion may also be provided on a side of the corrugated portion 1112 facing away from the first flat portion 1111. That is, the corrugated portion 1112 is provided at the edge of the vibrating portion 111 and spaced apart from the connecting portion 112 by a spacing. The connecting portion 112 is connected to the second flat portion 1113. In order to balance the air pressure on two opposing sides of the diaphragm 11, the vibration portion 111 defines a plurality of through holes, which enable the air flow to flow on two opposing sides of the diaphragm 11, so that the air pressure on the two opposing sides of the diaphragm 11 is balanced to a certain extent.

The corrugated structure formed by the corrugated portion 1112 makes the corrugated portion 1112 is different from the first flat portion 1111 and the second flat portion 1113 in shape, which is helpful for reducing the stress across the diaphragm 11. The compliance of the diaphragm can be improved with configuration of the corrugated structure. In addition, the corrugated portion 1112 is prone to cracking and failure due to the existence of corrugations or wrinkles. The deeper the wrinkles, the sharper the shape, such that the risk of cracking and failure of the diaphragm 11 is higher.

In view of the problem that the corrugated portion 1112 is relatively fragile due to the existence of wrinkles, the corrugated structure of the diaphragm 11 provided in some embodiments of the present disclosure is made of a material including at least silicon nitride, so that the flexural rigidity of the corrugated portion is larger than that of the other portions of the diaphragm 11. By using a material of the corrugated structure with a flexural rigidity higher than that of other portions, the corrugated structure formed by the corrugated portion 1112 has higher structural strength than other portions, thereby reducing the risk of cracking and failure of the diaphragm 11.

In practice, the corrugated structure may be made of silicon nitride and portions of the diaphragm 11 other than the corrugated structure may be made of polysilicon. That is, the first flat portion 1111 and the second flat portion 1113 may be made of polysilicon material, and the corrugated portion 1112 may be made of silicon nitride material 102. Alternatively, graphene may be used as a reinforcing material to improve the flexural rigidity at the corrugated structure of the diaphragm 11. Alternatively, other materials with higher flexural rigidity may be used as fabrication materials for the corrugated portion 1112. In addition, during the fabrication of the diaphragm 11, for a variety of materials, a deposition and etching process can be used, so that materials with different flexural rigidities can be integrated in different portions of the diaphragm 11.

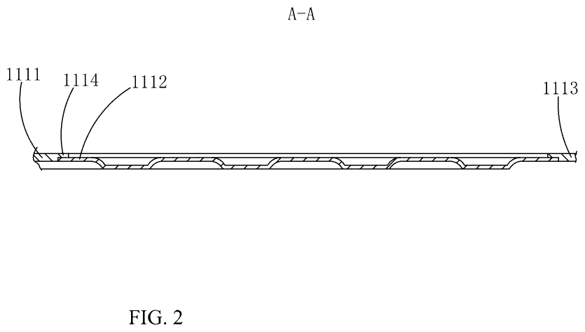

As shown in FIGS. 1 and 2, the corrugated portion 1112 of the diaphragm 11 may be made of a material having a higher flexural rigidity to replace a material having the same flexural rigidity as other portions in the related technologies.

Referring to FIGS. 1 and 2, the first flat portion 1111 and the second flat portion 1113 each have a protrusion portion 1114 extending from a side of one end of the first flat portion 1111 or the second flat portion 1113 close to the corrugated portion 1112, and each protrusion portion 1114 is superimposed on an edge of the corrugated portion 1112.

Each of the first flat portion 1111 and the second flat portion 1113 is provided with the protrusion portion 1114 at the edge of the first flat portion 1111 or the second flat portion 1113 close to the corrugated portion 1112. Each protrusion portion 1114 may be integrally formed with the first flat portion 1111 and the second flat portion 1113 to form part of the first flat portion 1111 and the second flat portion 1113. In addition, the protrusion portion 1114 is superimposed on the edge of the corrugated portion 1112. By disposing the protrusion portion 1114 on the corrugated portion 1112, the edge of the first flat portion 1111 and the edge of the corrugated portion 1112 form an additional connection relationship and the edge of the second flat portion 1113 and the edge of the corrugated portion 1112 form an additional connection relationship. That is, with aid of the protrusion portion 1114, it is possible to establish another connection relationship between the first flat portion 1111 and the corrugated portion 1112, and between the second flat portion 1113 and the corrugated portion 1112, so that the protrusion portion 1114 is superimposed on the corrugated portion 1112. In this way, when the first flat portion 1111 and the second flat portion 1113 are made of a material different from material of the corrugated portion 1112, the connection between the first flat portion 1111 and the corrugated portion 1112 and the connection between the second flat portion 1113 and the corrugated portion 1112 can be further enhanced by forming protrusion portion on the edge of each of the first flat portion 1111 and the second flat portion 1113.

In an actual situation, both sides of the end of the first flat portion 1111 close to the corrugated portion 1112 or both sides of the end of the second flat portion 1113 close to the corrugated portion 1112 may be formed with protrusion portions 1114, so as to wrap the edge of the corrugated portion 1112. Therefore, the edge of the corrugated portion 1112 is snaped into the first flat portion 1111 or the second flat portion 1113. Alternatively, it is possible to form a multi-layer stacking (overlapping) at the connection between the corrugated portion 1112 and the first flat portion 1111, or at the connection between the corrugated portion 1112 and the second flat portion, such that a connection area between the corrugated portion 1112 and the first flat portion 1111, or between the corrugated portion 1112 and the second flat portion 1113 may also be increased.

In some embodiments, a thickness of the corrugated portion 1112 is smaller than a thickness of the first flat portion 1111.

When the corrugated portion 1112 is made of a material with higher flexural rigidity as a whole, the corrugated portion 1112 can be made thinner to improve the mechanical sensitivity.

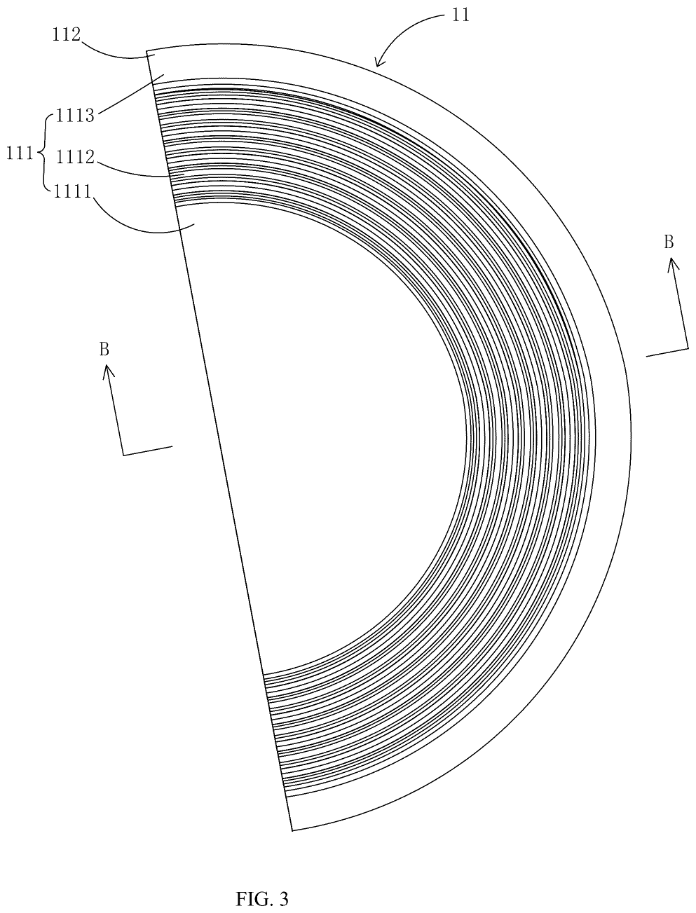

As shown in FIGS. 3 to 5, in order to enhance the corrugated structure of the diaphragm 11, the corrugated portion 1112 may be provided with a reinforcing layer 102. By providing the reinforcing layer 102 having a higher flexural rigidity, the flexural rigidity of the corrugated portion 1112 may be enhanced. The reinforcing layer 102 may be provided on top of the corrugated portion 1112. In actual situations, the reinforcing layer 102 may also be provided at the bottom of the corrugated portion 1112, or may be provided at both the top and bottom of the corrugated portion 1112. That is, the reinforcing layer 102 may be provided on a side of the corrugated portion 1112 close to the back plate and/or on a side of the corrugated portion 1112 away from the back plate.

If the reinforcing layer 102 is provided in the corrugated portion 1112, the corrugated portion 1112 may include a base layer 101 having one end connected to the first flat portion 1111 and the other end connected to the second flat portion 1113, and a reinforcing layer 102 disposed on the base layer 101. The reinforcing layer 102 includes a silicon nitride material.

The base layer 101 includes a polysilicon material. When the base layer 101 of the corrugated structure has the same flexural rigidity as the other portions of the microphone, adopting the reinforcing layer 102 with higher flexural rigidity can enable the corrugated structure (i.e., the corrugated portion 1112) to have a higher structural strength than the other portions.

Therefore, when the corrugated portion 1112 includes a multi-layer structure, the adverse effect caused by the high stress concentration on the base layer 101 having a lower flexural rigidity may be counteracted or partially eliminated by the reinforcing layer 102 having a higher flexural rigidity. The reinforcing layer 102 with the higher flexural rigidity is provided to improve the deformation resistance of the corrugated portion 1112, thereby reducing the risk of fracture failure.

In practice, the base layer 101 may also include a silicon nitride material, thereby forming a multi-layer silicon nitride structure including the base layer 101 and the reinforcing layer 102, and effectively ensuring the structural strength at the corrugated structure.

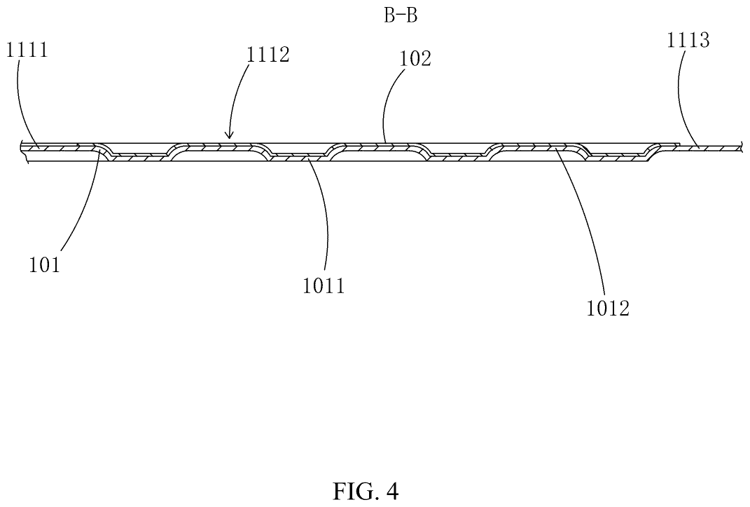

As shown in FIG. 4, in some embodiments, the reinforcing layer 102 may cover the entire base layer 101 in the direction from the center to the edge of the first flat portion 1111.

The reinforcing layer 102 may entirely cover the base layer 101, thereby facilitating forming of the reinforcing layer 102 and ensuring the overall structural strength of the reinforcing layer 102. During forming of the reinforcing layer 102, the reinforcing layer 102 may cover only one side of the base layer 101, or cover both sides of the base layer 101.

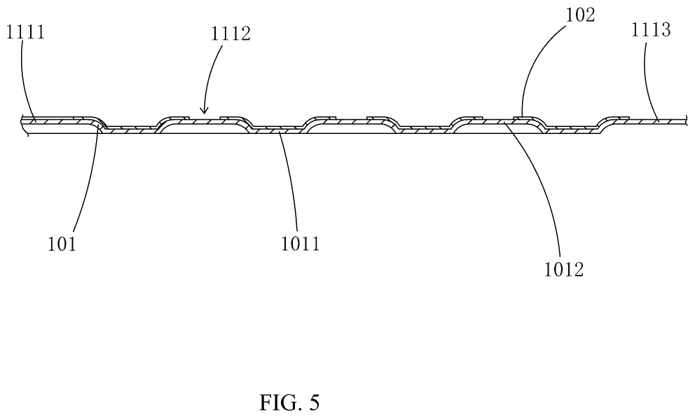

Furthermore, the reinforcing layer 102 may cover only a portion of the base layer 101. As shown in FIG. 5, in some embodiments, the base layer 101 may include concave portions 1011 and convex portions 1012 that are alternatingly disposed in the direction from the center to the edge of the first flat portion 1111. There are a plurality of reinforcing layers 102 in the direction from the center to the edge of the first flat portion 1111. Each reinforcing layer 102 is disposed on a respective entire concave portion 1011 and a portion of each of a pair of convex portions 1012 adjacent to the respective concave portion 1011, where adjacent reinforcing layers 102 located on a same convex portion 1012 are spaced apart from each other by a spacing.

That is, the plurality of reinforcing layers 102 are spaced on the base layer 101, and each reinforcing layer 102 is provided corresponding to the respective concave portion 1011 and the portion of each of the pair of convex portions 1012 of the base layer 101. Therefore, material used for the reinforcing layers 102 can be saved, and the mechanical sensitivity of the base layer 101 not superimposed with the reinforcing layer 102 can be ensured.

In some embodiments, each of the concave portions 1011 and each of the convex portions 1012 may have a flat extension length, such that the curved portion does not have wrinkles in a sharp shape as a result of being directly joined together. Stress concentration in the corrugated structure can be avoided by making the corrugated structure form a smooth edge without sharp corners. The use of the smooth edges reduces the failure rate of the diaphragm 11 during operation, which is conducive to improving the life of the product.

Furthermore, a thickness of each reinforcing layer 102 may be smaller than the thickness of the base layer 101.

The reinforcing layer 102 can be attached to the base layer 101 in a smaller thickness, so that the flexural rigidity of the corrugated structure is enhanced without adversely affecting the characteristics of the corrugated portion 1112.

In some embodiments, a junction of the corrugated portion 1112 with the first flat portion 1111 and a junction of the corrugated portion 1112 with the second flat portion 1113 may be kept flush with each other.

That is, the corrugated portion 1112, the first flat portion 1111, and the second flat portion 1113 may have a same thickness at the edge (junction) of each of the corrugated portion 1112, the first flat portion 1111, and the second flat portion 1113. When the corrugated portion 1112 is connected to the first flat portion 1111 and the second flat portion 1113, two opposing sides of the corrugated portion 1112 are in an aligned state (in a same horizontal state). Therefore, the junction between the corrugated portion 1112 and the first flat portion 1111 and the junction between the corrugated portion 1112 and the second flat portion 1113 lie on a same plane, so that positioning is simple. The fabrication and forming process of the diaphragm 11 can be simplified, which is advantageous to form the diaphragm 11 integrated with different materials through deposition and etching processes.

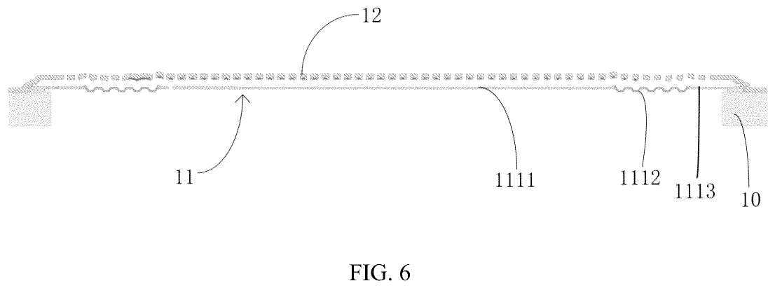

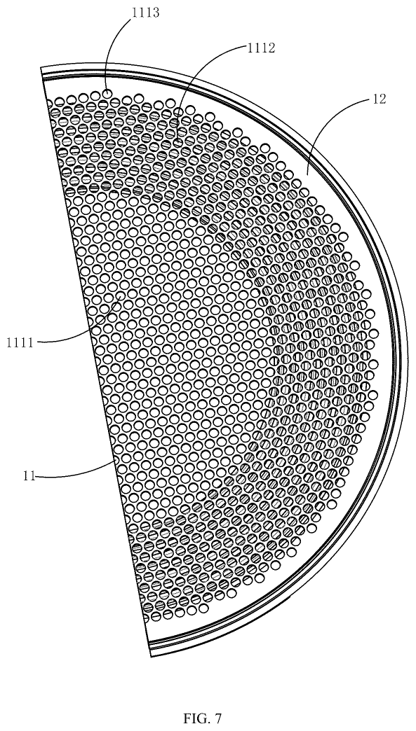

Some embodiments of the present disclosure further provide a MEMS microphone. As shown in FIGS. 6 and 7, the MEMS microphone includes a substrate 10 having a back cavity, and a capacitive structure disposed on the substrate 10. The capacitive structure includes a diaphragm 11, and a back plate 12 spaced apart from the diaphragm 11, and the diaphragm 11 is the diaphragm 11 described in above embodiments.

A vibration gap is defined between the vibration portion 111 of the diaphragm 11 and the back plate 12, and thus a capacitive structure is formed. When the vibration portion 111 of the diaphragm 11 is affected by the acoustic wave signal, the diaphragm 11 vibrates, and the distance between the diaphragm 11 and the back plate 12 changes, resulting in a change in the capacitance value. Therefore, acoustic signals can be converted into electrical signals. Since the corrugated portion 1112 with higher flexural rigidity is adopted or the reinforcing layer 102 is used to improve the flexural rigidity of the corrugated portion 1112, the impact resistance of the diaphragm 11 is improved, and the probability of rupture and failure of the diaphragm 11 is reduced. The reinforcing layer 102 may be provided on a side of the corrugated portion 1112 adjacent to the back plate 12 and/or on a side of the corrugated portion 1112 away from the back plate 12.

Those of ordinary skill in the art will appreciate that the embodiments described above are embodiments that implement the present disclosure, and that in practical application various changes may be made to them in form and detail without departing from the spirit and scope of the present disclosure.

What is claimed is:

1. A diaphragm, comprising a vibrating portion and a connecting portion provided around the vibrating portion; wherein
the vibrating portion includes a first flat portion disposed in a central position of the vibrating portion, a corrugated portion disposed around the first flat portion, and a second flat portion disposed around the corrugated portion;
the corrugated portion extends in a direction from a center to an edge of the first flat portion, the corrugated portion has a flexural rigidity larger than a flexural rigidity of the first flat portion and a flexural rigidity of the second flat portion, and the corrugated portion is made of a material including at least silicon nitride.

2. The diaphragm of claim 1, wherein:
each of the first flat portion and the second flat portion includes a polysilicon material, and the corrugated portion includes a silicon nitride material.

3. The diaphragm of claim 1, wherein:
the corrugated portion includes a base layer having an end connected with the first flat portion and another end connected with the second flat portion, and at least one reinforcing layer disposed on the base layer, wherein the at least one reinforcing layer includes a silicon nitride material.

4. The diaphragm of claim 3, wherein:
the base layer includes a polysilicon or silicon nitride material.

5. The diaphragm of claim 3, wherein:
the at least one reinforcing layer is entirely disposed on the base layer in the direction from the center to the edge of the first flat portion.

6. The diaphragm of claim 3, wherein:
the base layer includes concave portions and convex portions that are alternatingly disposed in the direction from the center to the edge of the first flat portion;
the at least one reinforcing layer is embodied as a plurality of reinforcing layers in the direction from the center to the edge of the first flat portion;
each respective reinforcing layer of the plurality of reinforcing layers is disposed on a respective entire concave portion and a portion of each of a pair of convex portions adjacent to the respective concave portion; and
adjacent reinforcing layers located on a same convex portion of the convex portions are spaced apart from each other by a spacing.

7. The diaphragm of claim 1, wherein:
the first flat portion and the second flat portion each have a protrusion portion extending from a side of an end of the first flat portion or the second flat portion close to the corrugated portion, and the protrusion portion is disposed on an edge of the corrugated portion.

8. The diaphragm of claim 7, wherein:
the corrugated portion has a thickness less than a thickness of the first flat portion.

9. A MEMS microphone, comprising a substrate having a back cavity and a capacitive structure disposed on the substrate, wherein the capacitive structure includes a diaphragm and a back plate disposed spaced apart from the diaphragm, and the diaphragm is the diaphragm of claim 1.

10. The MEMS microphone of claim 9, wherein:
the corrugated portion of the diaphragm includes a base layer having an end connected with the first flat portion and another end connected with the second flat portion, and the at least one reinforcing layer disposed on the base layer; and
the at least one reinforcing layer includes a silicon nitride material, and the at least one reinforcing layer is provided on at least one of a side of the corrugated portion close to the back plate and a side of the corrugated portion facing away from the back plate.

11. The MEMS microphone of claim 10, wherein:
the base layer includes a polysilicon or silicon nitride material, and each of the first flat portion and the second flat portion includes a polysilicon material.

12. The MEMS microphone of claim 10, wherein:
the at least one reinforcing layer is entirely disposed on the base layer in the direction from the center to the edge of the first flat portion.

13. The MEMS microphone of claim 10, wherein:
the base layer includes concave portions and convex portions that are alternatingly disposed in the direction from the center to the edge of the first flat portion;
the at least one reinforcing layer is embodied as a plurality of reinforcing layers in the direction from the center to the edge of the first flat portion;
each respective reinforcing layer of the plurality of reinforcing layers is disposed on a respective entire concave portion and a portion of each of a pair of convex portions adjacent to the respective concave portion; and
adjacent reinforcing layers located on a same convex portion of the convex portions are spaced apart from each other by a spacing.

14. The MEMS microphone of claim 9, wherein:
the first flat portion and the second flat portion each have a protrusion portion extending from a side of an end of the first flat portion or the second flat portion close to the corrugated portion, and the protrusion portion is disposed on an edge of the corrugated portion.

15. The MEMS microphone of claim 14, wherein:
the corrugated portion has a thickness less than a thickness of the first flat portion.
